(19) United States
(12) Patent Application Publication
(10) Pub. No.: US 2010/0163974 A1
(43) Pub. Date: Jul. 1, 2010

(54) SEMICONDUCTOR DEVICE WITH VERTICAL CHANNEL TRANSISTOR AND METHOD FOR FABRICATING THE SAME

(76) Inventor: Seung-Chul Oh, Gyeonggi-do (KR)

Correspondence Address: IP & T Law Firm PLC, 7700 Little River Turnpike, Suite 207, Annandale, VA, 22003, US

(21) Appl. No.: 12/492,831

(22) Filed: Jun. 26, 2009

(30) Foreign Application Priority Data
Dec. 29, 2008 (KR) 10-2008-0135535

(51) Int. Cl. H01L 29/78; H01L 21/764

(52) U.S. Cl. 257/329; 438/421; 257/E21.573; 257/E29.262

(57) ABSTRACT

A method for fabricating a semiconductor device including a vertical channel transistor includes providing a substrate including a semiconductor pillar, forming a gate electrode surrounding the semiconductor pillar, forming an impurity region for a bit line by doping impurities into the substrate and forming a device isolation trench by etching a portion of the substrate including the impurity region to a certain depth, thereby defining the bit line, wherein the impurity doping is performed with given concentration so as to form the impurity region under the semiconductor pillar.

### CROSS-REFERENCE TO RELATED APPLICATIONS

The present invention claims priority of Korean patent application number 10-2008-0135535, filed on Dec. 29, 2008, the disclosure of which is incorporated herein by reference in its entirety.

### BACKGROUND OF THE INVENTION

The present invention relates to technology for fabricating a semiconductor device, and more particularly, to a semiconductor device with a vertical channel transistor and a method for fabricating the same.

In general, a unit cell of a dynamic random access memory (DRAM) device includes one transistor used as a selection element and one capacitor used as a storage element. Recently, as the DRAM device is down-sized, a vertical channel transistor is used instead of a conventional planar type transistor as the selection element.

FIGS. 1A to 1F illustrate a method for fabricating a conventional vertical channel transistor.

Referring to FIG. 1A, a hard mask pattern 11 is formed on a substrate 10. Herein, the hard mask pattern 11 is formed to have an island type and a plurality of hard mask patterns is arranged in a first and a second direction, wherein the second direction intersects with the first direction.

Referring to FIG. 1B, an upper semiconductor pillar 10a is formed by etching a portion of the substrate 10 to a certain depth using the hard mask pattern 11 as an etch barrier.

After forming a material layer for a spacer on an entire surface of a resultant structure including the upper semiconductor pillar 10A, a spacer 12 is formed on sidewalls of the hard mask pattern 11 and the upper semiconductor pillar 10A by etching-back the material layer.

Referring to FIG. 1C, a lower semiconductor pillar 10B is formed by etching a portion of the substrate 10 to a given depth using the hard mask pattern 11 and the spacer 12 as an etch barrier. Herein, the lower semiconductor pillar 10B is connected to the upper semiconductor pillar 10a as one body. As a result, a semiconductor pillar 100 including the upper semiconductor pillar 10A and the lower semiconductor pillar 10B is formed.

Referring to FIG. 1D, the lower semiconductor pillar 10B is recessed up to a certain width using the hard mask pattern 11 and the spacer 12 as an etch barrier. The recessed lower semiconductor pillar is indicated by a reference numeral 10B′.

Then, a gate insulating layer 13 is formed on an exposed surface of the substrate 10 including the recessed lower semiconductor pillar 10B′.

After forming a conducting layer for a gate electrode on an entire surface of a resultant structure including the gate insulating layer 13, the conducting layer is etched-back until the gate insulating layer 13 is exposed. As a result, a gate electrode 14 is formed to surround the recessed lower semiconductor pillar 10B′.

Referring to FIG. 1E, an impurity region 15 for a bit line is formed by doping impurities, e.g., N type impurities, into a portion of the substrate 10 disposed between semiconductor pillars 100.

After that, an insulating layer 16 is formed on an entire surface of a resultant structure including the impurity region 15.

Referring to FIG. 1F, a mask pattern (not shown) for forming a device isolation trench is formed on the insulating layer 16.

After exposing a portion of the substrate 10 by etching the insulating layer 16 using the mask pattern as an etch barrier, the exposed portion of the substrate 10 is etched to a certain depth. As a result, the device isolation trench T extended in a direction running parallel to the second direction is formed in a portion of the substrate 10 disposed between columns of the semiconductor pillars 100 arranged in the second direction. Herein, the device isolation trench T is formed to have a depth of penetrating the impurity region 15 and thus a buried bit line 15A is formed to surround the semiconductor pillar 100 and extended in the second direction. As the device isolation trench T is formed, the etched insulating layer is indicated by a reference numeral 16′.

Subsequently, although it is not shown, a DRAM device is fabricated by sequentially performing a process of forming a word line that is extended in the first direction and electrically connected to the gate electrode 14 and a process of forming a capacitor on the semiconductor pillar 100 that is exposed by removing the hard mask pattern 11.

Since the buried bit line 15A is formed by performing the impurity doping process, its resistance significantly increases. The increase of the resistance becomes more serious as the size of the semiconductor device is reduced. However, when increasing doping concentration of the impurities to suppress the increase of the resistance, the performance of the transistor is deteriorated by a hot carrier effect.

Therefore, there is required to develop technology of reducing the resistance of the buried bit line as well as preventing the performance deterioration of the transistor in the vertical channel transistor structure.

### SUMMARY OF THE INVENTION

Embodiments of the present invention are directed to provide a semiconductor device with a vertical channel transistor and a method for fabricating the same, which are able to reduce the resistance of a bit line and prevent the performance deterioration of the transistor by disposing a impurity region for the bit line under a semiconductor pillar while increasing doping concentration of impurities to form the bit line.

In accordance with an aspect of the present invention, there is provided a method for fabricating a semiconductor device including a vertical channel transistor. The method includes providing a substrate including a semiconductor pillar, forming a gate electrode surrounding the semiconductor pillar, forming an impurity region for a bit line by doping impurities into the substrate, and forming a device isolation trench by etching a portion of the substrate including the impurity region to a certain depth, thereby defining the bit line, wherein the impurity doping is performed with given concentration so as to form the impurity region under the semiconductor pillar.

In accordance with another aspect of the present invention, there is provided a semiconductor device including a vertical channel transistor. The semiconductor device includes a substrate including a semiconductor pillar, a gate electrode surrounding the semiconductor pillar, and a bit line defined by a device isolation trench and formed by doping impurities into the substrate, wherein the doping concentration of the impurities has a given value so as to form the bit line under the semiconductor pillar.

In accordance with another aspect of the present invention, there is provided a semiconductor device including a vertical channel transistor. The semiconductor device includes a substrate including a semiconductor pillar, a gate electrode surrounding the semiconductor pillar, and a bit line defined by a device isolation trench and formed by doping impurities into the substrate, wherein the bit line extends across an entire width of an area of the substrate covered by the semiconductor pillar.

### BRIEF DESCRIPTION OF THE DRAWINGS

FIGS. 1A to 1F illustrate a method for fabricating a conventional vertical channel transistor.

FIGS. 2A to 2F illustrate a method for fabricating a semiconductor device including a vertical channel transistor in accordance with an embodiment of the present invention.

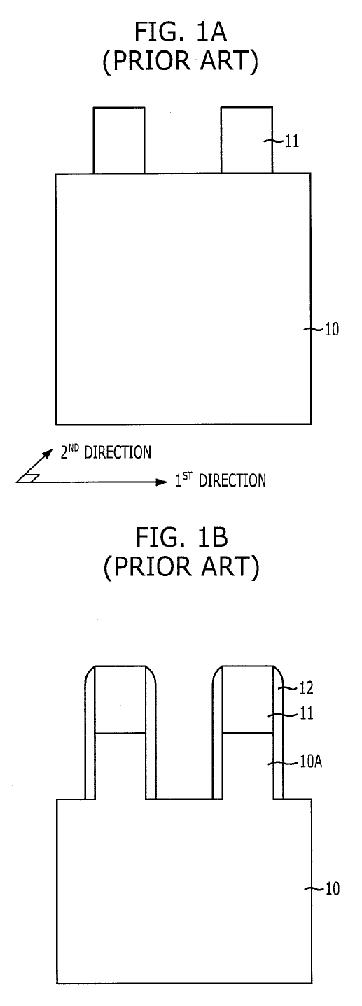

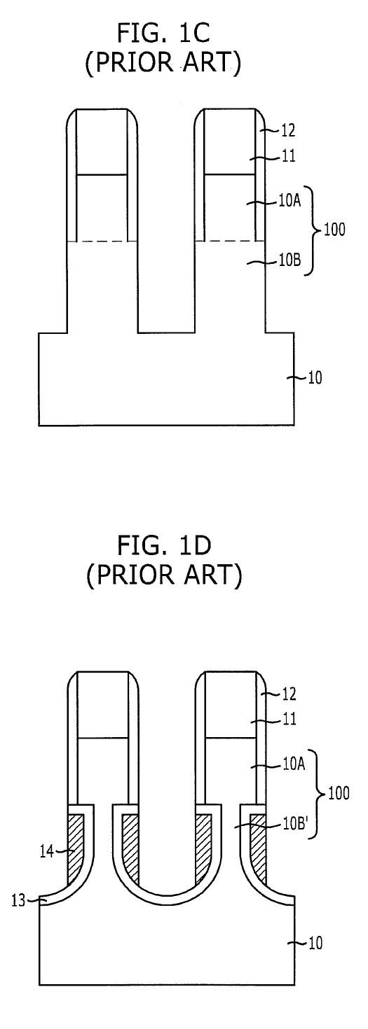

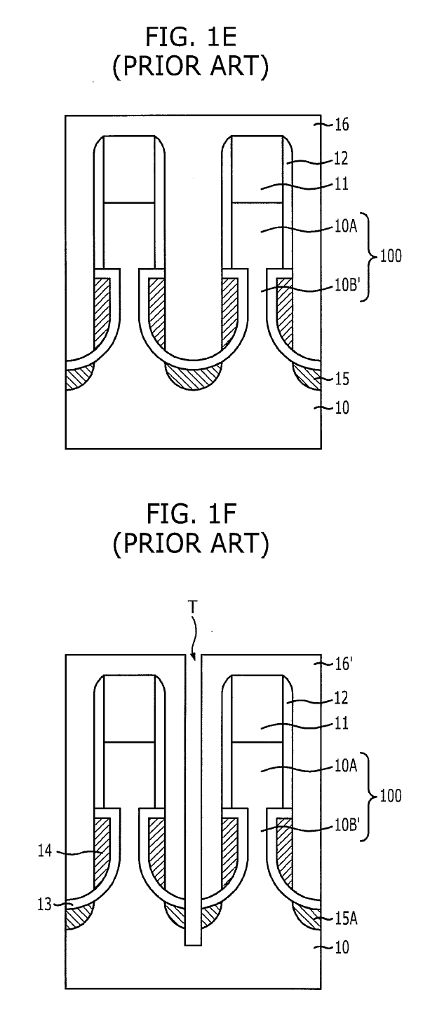

### DESCRIPTION OF SPECIFIC EMBODIMENTS

Other objects and advantages of the present invention can be understood by the following description, and become apparent with reference to the embodiments of the present invention.

In the figures, the dimensions of layers and regions are exemplary and may not be exact. It will also be understood that when a layer (or film) is referred to as being ‘on’ another layer or substrate, it can be directly on the other layer or substrate, or intervening layers may also be present. Furthermore, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

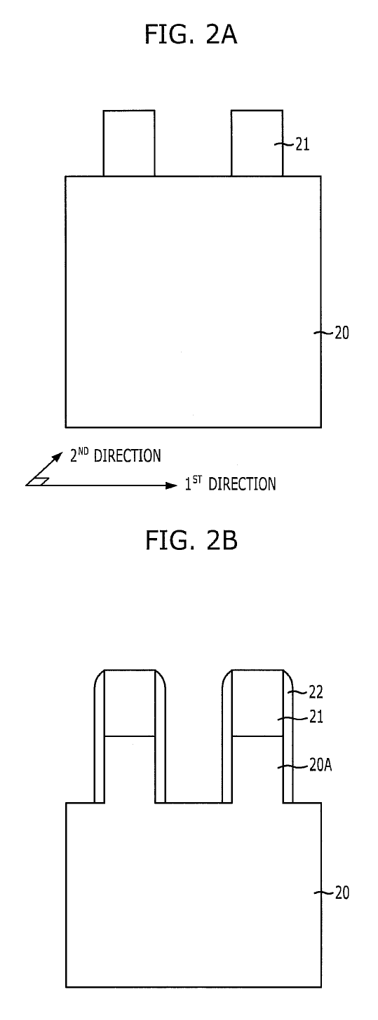

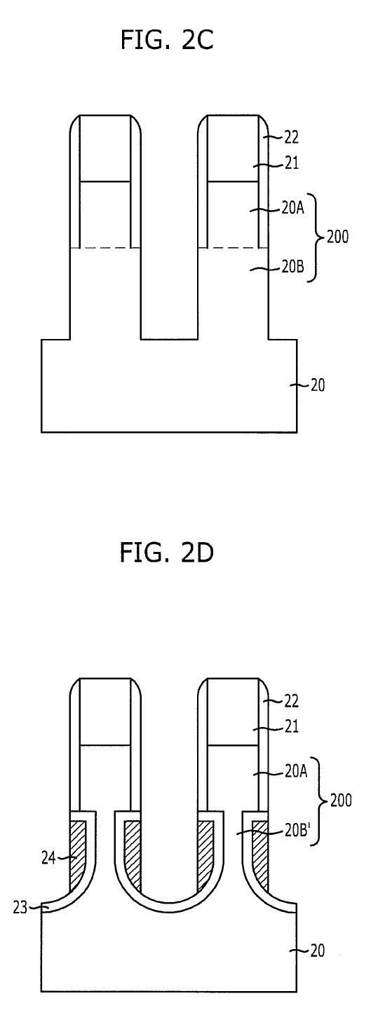

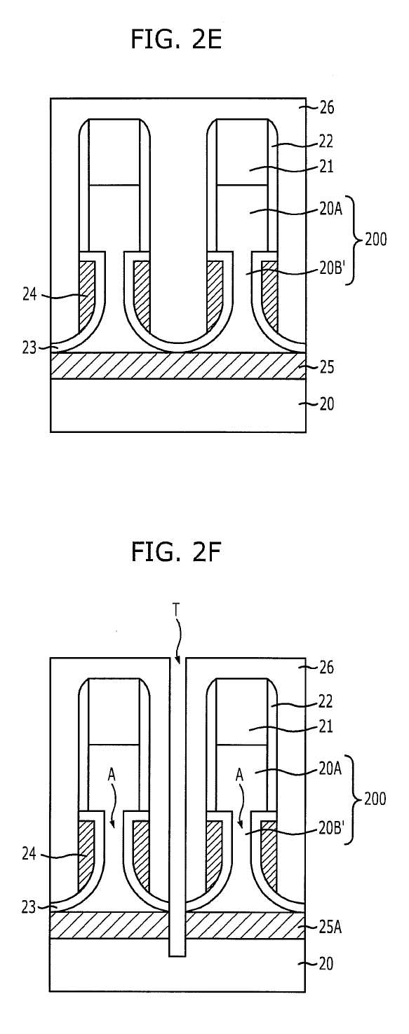

FIGS. 2A to 2F illustrate a method for fabricating a semiconductor device including a vertical channel transistor in accordance with a preferred embodiment of the present invention. In particular, FIG. 2F describes the semiconductor device including the vertical channel transistor in accordance with the preferred embodiment of the present invention.

Referring to FIG. 2A, a hard mask pattern 21 is formed on a substrate 20. Herein, the hard mask pattern 21 is formed to have an island type and a plurality of hard mask patterns is disposed in a first direction and a second direction, wherein the second direction intersects with the first direction.

Referring to FIG. 2B, an upper semiconductor pillar 20A is formed by etching a portion of the substrate 20 to a certain depth using the hard mask pattern 21 as an etch barrier.

After forming a material layer for a spacer on an entire surface of a resultant structure including the upper semiconductor pillar 20A, a spacer 22 is formed on sidewalls of the hard mask pattern 21 and the upper semiconductor pillar 20A by etching-back the material layer.

Referring to FIG. 2C, a lower semiconductor pillar 20B is formed by etching a portion of the substrate 20 to a given depth using the hard mask pattern 21 and the spacer 22 as an etch barrier. Herein, the lower semiconductor pillar 20B is connected to the upper semiconductor pillar 20A as one body. As a result, a semiconductor pillar 200 including the upper semiconductor pillar 20A and the lower semiconductor pillar 20B is formed.

Referring to FIG. 2D, the lower semiconductor pillar 20B is recessed to or up to a certain width using the hard mask pattern 21 and the spacer 22 as an etch barrier. The recessed lower semiconductor pillar is indicated by a reference numeral 20B′.

Then, a gate insulating layer 23 is formed on an exposed surface of the substrate 20 including the recessed lower semiconductor pillar 20B′.

Subsequently, after forming a conducting layer for a gate electrode on an entire surface of a resultant structure including the gate insulating layer 23, the conducting layer is etched-back until the gate insulating layer 23 is exposed. As a result, a gate electrode 24 is formed to surround the recessed lower semiconductor pillar 20B′.

Referring to FIG. 2E, an impurity region 25 for a bit line is formed by doping impurities into the substrate 20. Herein, the bit line impurity region 25 is disposed in not only a portion of the substrate 20 between semiconductor pillars 200 but also a portion of the substrate 20 under the semiconductor pillar 200 so that the bit line impurity region 25 is disposed over an entire region of the substrate 20 by doping impurities with high concentration. The impurities are N type impurities and may include phosphorus (P) or arsenic (As). The concentration of the impurities may be greater than approximately 10¹⁵ atoms/cm². An effect of doping the impurities with the high concentration will be described later.

Then, an insulating layer 26 is formed on an entire surface of a resultant structure including the bit line impurity region 25.

Referring to FIG. 2F, a mask pattern (not shown) for forming a device isolation trench is formed on the insulating layer 26.

Then, after exposing a portion of the substrate 20 by etching the insulating layer 26 using the mask pattern as an etch barrier, the exposed portion of the substrate 20 is etched to a certain depth. As a result, the device isolation trench T extended in a direction running parallel to the second direction is formed in a portion of the substrate 20 disposed between columns of the semiconductor pillars 200 arranged in the second direction. Herein, the device isolation trench T is formed to have a depth that penetrates the bit line impurity region 25 and thus a buried bit line 25A is formed to be disposed under the semiconductor pillar 200 and extended in the second direction. As the device isolation trench T is formed, the etched insulating layer is indicated by a reference numeral 26′.

Referring to FIG. 2F, advantages of the vertical channel transistor in accordance with the preferred embodiment of the present invention will be described.

First of all, since the buried bit line 25A is formed by performing the impurity doping with the high concentration, the resistance of the buried bit line 25A is substantially reduced.

Furthermore, a fully depleted channel, referring to a reference numeral A, may be formed by the gate electrode 24 surrounding the semiconductor pillar 200 and the buried bit line 25A, it is possible to prevent the performance deterioration of the transistor due to a hot carrier effect that occurs when the transistor operates.

In the semiconductor device and the method for fabricating the same in accordance with the present invention, since the bit line impurity region is formed to be disposed under the semiconductor pillar while increasing the doping concentration of the impurities to form the bit line, it is possible to reduce the resistance of the bit line and prevent the performance deterioration of the transistor.

While the present invention has been described with respect to the specific embodiments, it will be apparent to those skilled in the art that various changes and modifications may be made without departing from the spirit and scope of the invention as defined in the following claims.

For instance, although a sequence of the processes of forming the semiconductor pillar and the gate electrode surrounding the semiconductor pillar is described with reference to FIGS. 2A to 2D, the invention is not limited thereto and thus the semiconductor pillar and the gate electrode may be formed by other various processes.

What is claimed is:

1. A method for fabricating a semiconductor device including a vertical channel transistor, the method comprising:
providing a substrate including a semiconductor pillar;
forming a gate electrode surrounding the semiconductor pillar;
forming an impurity region for a bit line by doping impurities into the substrate; and
forming a device isolation trench by etching a portion of the substrate including the impurity region to a certain depth, thereby defining the bit line,
wherein the impurity doping is performed with given concentration so as to form the impurity region under the semiconductor pillar.

2. The method of claim 1, wherein the impurities are N type impurities.

3. The method of claim 1, wherein the given concentration is greater than approximately 10¹⁵ atoms/cm².

4. A semiconductor device including a vertical channel transistor, the semiconductor device comprising:
a substrate including a semiconductor pillar;
a gate electrode surrounding the semiconductor pillar; and
a bit line defined by a device isolation trench and formed by doping impurities into the substrate,
wherein the doping concentration of the impurities has a given value so as to form the bit line under the semiconductor pillar.

5. The semiconductor device of claim 4, wherein the impurities are N type impurities.

6. The semiconductor device of claim 4, wherein the given value is greater than approximately 10¹⁵ atoms/cm².

7. The semiconductor device of claim 4, wherein the semiconductor pillar surrounded by the gate electrode includes a fully depleted channel.

8. A semiconductor device including a vertical channel transistor, the semiconductor device comprising:
a substrate including a semiconductor pillar;
a gate electrode surrounding the semiconductor pillar; and
a bit line bounded by a device isolation trench and formed by doping impurities into the substrate,
wherein the bit line extends across an entire width of an area of the substrate covered by the semiconductor pillar.

9. The semiconductor device of claim 8, wherein the impurities are N type impurities.

10. The semiconductor device of claim 8, wherein the impurity doping is performed with an impurity concentration greater than approximately 10¹⁵ atoms/cm².

11. The semiconductor device of claim 8, wherein the semiconductor pillar surrounded by the gate electrode includes a fully depleted channel.
